(19) United States
(12) Patent Application Publication
(10) Pub. No.: US 2026/0077447 A1
(43) Pub. Date: Mar. 19, 2026

(54) POLISHING PAD, PREPARATION METHOD THEREOF AND PREPARATION METHOD OF SEMICONDUCTOR DEVICE USING THE SAME

(71) Applicant: Enpulse Co., Ltd., Chungcheongnam-do (KR)

(72) Inventors: Yujin SHIN, Chungcheongnam-do (KR); Kyunghwan KIM, Chungcheongnam-do (KR); Jongwook YOON, Chungcheongnam-do (KR); Jangwon SEO, Chungcheongnam-do (KR)

(21) Appl. No.: 19/277,426

(22) Filed: Jul. 23, 2025

(30) Foreign Application Priority Data
Sep. 13, 2024 (KR) 10-2024-0126145

(51) Int. Cl. B24B 37/26; B24B 37/24; H01L 21/304

(52) U.S. Cl. CPC B24B 37/26; B24B 37/24; H10P 52/00

(57) ABSTRACT

According to embodiments of the present invention, there are provided a polishing pad, a process for preparing a polishing pad, and a process for preparing a semiconductor device using the polishing pad. The polishing pad comprises a sub pad and a top pad disposed on the sub pad and comprising a first region and a second region having different densities, wherein the difference between the density of the first region and the density of the second region is 0.03 g/cm³ or more. A high polishing rate can be provided in the central region of an object to be polished, and enhanced polishing flatness can be provided in the edge region of the object to be polished.

### CROSS-REFERENCE TO RELATED APPLICATION(S)

This patent document claims the priority and benefits of Korean Patent Application No. 10-2024-0126145 filed on Sep. 13, 2024, the disclosure of which is incorporated herein by reference in its entirety.

### TECHNICAL FIELD

The present invention relates to a polishing pad, to a process for preparing the same, and to a process for preparing a semiconductor device using the same.

### BACKGROUND ART

A chemical mechanical planarization (CMP) process may be carried out for various purposes in various technical fields. For example, a CMP process may be used to planarize the surfaces of materials and substrates used in semiconductor devices, electronic components, optical components, and the like, remove aggregated substances, resolve damage to crystal lattices, and remove surface defects and contaminants.

In a CMP process, a polishing pad may be used to polish the surface of an object to be polished. For example, the CMP process in a process for preparing semiconductors refers to a process in which a semiconductor substrate such as a wafer or die is fixed to a head and in contact with the surface of a polishing pad mounted on a platen, and the surface of the semiconductor substrate is then polished while the platen and the head are relatively rotated.

A polishing pad may be prepared using a polymer resin, for example, a polyurethane-based resin, and it may comprise grooves that support a large flow of a slurry on the surface and pores that support a fine flow thereof. The pores in a polishing pad may be formed by using a solid phase foaming agent, a gas phase foaming agent, or a liquid phase foaming agent, or by generating a gas by a chemical reaction.

Since a polishing pad interacts in direct contact with the surface of an object to be polished, such as a semiconductor substrate, it may have an impact on the processing quality of the surface of the polished object. For example, the diffusion and supply of a slurry on the surface to be polished, the external force acting on the surface to be polished, and the interaction between the polishing layer and the surface to be polished may vary depending on the structure, physical properties, and materials of the polishing layer adopted in the polishing pad. Accordingly, in order to secure polishing characteristics, such as the uniformity of thickness of the polished object, the flatness of the polished surface, or the polishing amount, at desired levels upon polishing, research is required on polishing pads that can provide more precise and reliable polishing quality.

### PRIOR ART DOCUMENT

### Patent Document

(Patent Document 1) Korean Patent No. 10-1690996

### DETAILED DESCRIPTION OF THE INVENTION

### Technical Problem

A technical problem to be solved by the present invention is to provide a polishing pad that comprises a top pad comprising a plurality of regions having different densities, whereby it can implement a high polishing rate for a film substance to be polished and can exhibit enhanced polishing uniformity in the edge region.

In addition, it is aimed to provide a process for preparing the polishing pad.

In addition, it is aimed to provide a process for preparing a semiconductor device using the polishing pad.

### Solution to the Problem

The polishing pad according to an embodiment of the present invention comprises a sub pad and a top pad disposed on the sub pad and comprising a first region and a second region having different densities, wherein the difference between the density of the first region and the density of the second region is 0.03 g/cm³ or more.

In the process for preparing a polishing pad according to another embodiment of the present invention, a first top pad layer may be attached to a portion of the upper side of a sub pad, and a second top pad layer having a different density from that of the first top pad layer may be attached to another portion of the upper side of the sub pad to prepare a polishing pad. The difference between the density of the first top pad layer and the density of the second top pad layer is 0.03 g/cm³ or more.

In the process for preparing a semiconductor device according to another embodiment of the present invention, the polishing pad may be mounted on a platen. A semiconductor substrate may be mounted on a head such that the surface, to be polished, of the semiconductor substrate is brought into contact with the top pad of the polishing pad. The polishing pad and the semiconductor substrate may be rotated relative to each other to polish the surface, to be polished, of the semiconductor substrate.

### Advantageous Effects of the Invention

The polishing pad according to an embodiment of the present invention comprises a top pad comprising a plurality of regions having different densities, wherein the difference in density between the plurality of regions is 0.03 g/cm³ or more. As a result, when a CMP process is carried out using the above polishing pad, high polishing characteristics for a semiconductor substrate such as a wafer can be secured while a desired level of polishing quality is provided at the center and edge.

For example, as the overall inflow and diffusion of a slurry on the surface, to be polished, of a semiconductor substrate is controlled, a high polishing rate and polishing uniformity can be secured at the center, while polishing uniformity can be enhanced in the edge region of the semiconductor substrate.

### BRIEF DESCRIPTION OF THE DRAWINGS

FIG. 1 is a schematic perspective view showing a polishing pad according to some embodiments of the present invention.

FIG. 2 is a schematic cross-sectional view showing a polishing pad according to some embodiments of the present invention.

FIG. 3 is a schematic plan view showing a polishing pad according to some embodiments of the present invention.

FIG. 4 is a schematic plan view showing a polishing pad according to some embodiments of the present invention.

FIG. 5 is a schematic plan view showing a polishing pad according to some embodiments of the present invention.

FIG. 6 is a perspective view showing a polishing pad according to some embodiments of the present invention.

FIG. 7 is a schematic process flow diagram for illustrating a process for preparing a semiconductor device according to some embodiments of the present invention.

FIG. 8 is a schematic cross-sectional view for illustrating the contact surface of a polishing pad and a semiconductor substrate.

FIG. 9a is a graph showing a polishing rate profile with respect to the distance from the center of a silicon wafer measured in Test Example 1 for each of Example 1, Example 2, and Comparative Example 1.

FIG. 9b is an enlarged graph of the polishing rate profile in the edge region in FIG. 9a.

FIG. 10a is a graph showing a polishing rate profile with respect to the distance from the center of a silicon wafer measured in Test Example 1 for each of Example 1, Example 2, and Comparative Example 2.

FIG. 10b is an enlarged graph of the polishing rate profile in the edge region in FIG. 10a.

FIG. 11a is a graph showing a polishing rate profile with respect to the distance from the center of a silicon wafer measured in Test Example 1 for each of Example 3, Example 4, and Comparative Example 3.

FIG. 11b is an enlarged graph of the polishing rate profile in the edge region in FIG. 11a.

### BEST MODE FOR CARRYING OUT THE INVENTION

Hereinafter, the present invention will be described in detail with reference to various embodiments. The embodiments are not limited to what has been disclosed below. The embodiments may be modified into various forms as long as the gist of the invention is not altered.

In this specification, terms referring to the respective components are used to distinguish them from each other and are not intended to limit the scope of the embodiment. In addition, in the present specification, a singular expression is interpreted to cover a plural number as well unless otherwise specified in the context.

Throughout the present specification, when a part is referred to as “comprising” an element, it is understood that other elements may be comprised, rather than other elements are excluded, unless specifically stated otherwise.

In the present specification, when one component is described to be disposed or formed on or under another component or connected or coupled to each other, it covers the cases where these components are directly or indirectly disposed, formed, connected, or coupled through another component. In addition, it should be understood that the criterion for the terms on and under of each component may vary depending on the direction in which the object is observed.

All numerical ranges related to the physical properties, dimensions, and the like of a component used herein are to be understood as being modified by the term “about,” unless otherwise indicated.

In the numerical range that limits the size of components, physical properties, and the like described in the present specification, when a numerical range limited with the upper limit only and a numerical range limited with the lower limit only are separately exemplified, it should be understood that a numerical range combining these upper and lower limits is also encompassed in the exemplary scope.

The terms first, second, and the like are used herein to describe various elements, and the elements should not be limited by the terms. But the components should not be limited by the terms. The terms are used for the purpose of distinguishing one element from another.

### Polishing Pad

The polishing pad according to embodiments of the present invention comprises a sub pad and a top pad disposed on the sub pad. The top pad comprises a first region and a second region having different densities. The difference between the density of the first region and the density of the second region is 0.03 g/cm³ or more.

Hereinafter, embodiments of the present invention will be described with reference to the drawings. However, this is intended to illustrate preferred embodiments of the present invention. The present invention is not limited to the structures, components, shapes, arrangement relationships, and the like shown in the drawings. For the sake of description, the sizes of individual elements in the appended drawings may be exaggeratedly depicted and do not indicate the actual sizes.

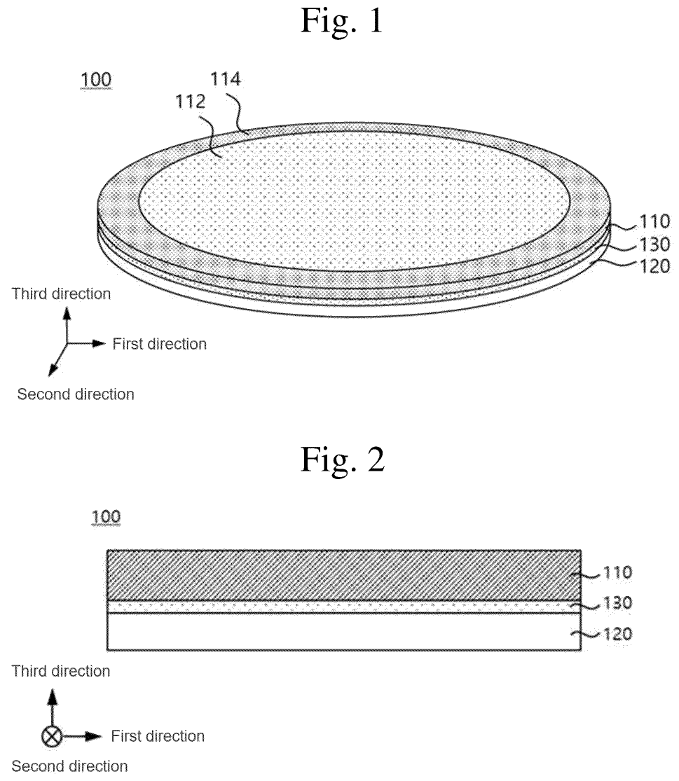

FIG. 1 is a schematic perspective view showing a polishing pad according to an embodiment of the present invention. FIG. 2 is a schematic cross-sectional view showing a polishing pad according to an embodiment of the present invention.

Referring to FIGS. 1 and 2, the polishing pad (100) comprises a sub pad (120) and a top pad (110) disposed on the sub pad (120). The top pad (110) may be attached to the upper side of the sub pad (120).

In an embodiment, the top pad (110) may be attached in direct contact with the upper side of the sub pad (120). In another embodiment, the top pad (110) may be attached to the upper side of the sub pad (120) via an adhesive layer (130).

The top pad (110) may comprise a first region (112) and a second region (114) that are distinguished from each other when observed in the upper side direction. Hereinafter, unless otherwise described, the “upper side direction” refers to the opposite direction to the direction in which the sub pad and top pad are laminated in that order. In the drawings, it refers to the opposite direction to the third direction.

The first region (112) and the second region (114) may have different densities. The difference between the density of the first region (112) and the density of the second region (114) may be 0.03 g/cm³ or more.

As the top pad (110) comprises a plurality of regions having a difference in density of 0.03 g/cm³ or more, a high polishing rate during a polishing process for an object to be polished can be provided, and the polishing uniformity at the edge of the polished object can be enhanced.

Since the surface of an object to be polished is polished through both a region with a relatively high density and a region with a relatively low density in a polishing procedure, the inflow and diffusion of a slurry can become easier, and enhanced polishing quality can be provided.

For example, as the density of the top pad increases, the removal rate for an object to be polished may increase, whereas the removal rate may appear uneven region by region. Further, as the polishing efficiency decreases steeply toward the edge of the surface to be polished, the polishing flatness in the edge region may deteriorate. In addition, as the density of the top pad decreases, the polishing efficiency for an object to be polished may decrease over the entire area of the surface, to be polished, of the object, whereby the desired polishing quality may not be provided.

According to an embodiment of the present invention, the first region (112) and the second region (114) have a difference in density of 0.03 g/cm³ or more. Thus, the inflow of a slurry can be facilitated through the region with a low density, and the removal rate due to friction can be increased through the region with a high density, whereby the polishing rate and polishing flatness can be enhanced together. Further, the polishing efficiency in the edge region of an object to be polished is prevented from steeply decreasing, whereby a desired level of removal rate can be secured, and the polishing flatness in the edge region can be improved.

If the difference between the density of the first region and the density of the second region is less than 0.03 g/cm³, the difference in density between the regions is too small. As a result, the polishing characteristics, as described above, induced or generated in a polishing procedure by the respective regions and the resulting interactions and synergies may not be substantially implemented.

The difference in density between the first region (112) and the second region (114) may be 0.15 g/cm³ or less. If the difference in density exceeds 0.15 g/cm³, the difference between the polishing characteristics by the first region and the polishing characteristics by the second region increases, whereby the polishing flatness may rather deteriorate.

In an embodiment, the difference between the density of the first region (112) and the density of the second region (114) may be 0.035 g/cm³ or more, 0.04 g/cm³ or more, 0.045 g/cm³ or more, or 0.05 g/cm³ or more, and may be 0.14 g/cm³ or less, 0.12 g/cm³ or less, 0.10 g/cm³ or less, 0.09 g/cm³ or less, 0.08 g/cm³ or less, 0.07 g/cm³ or less, or 0.06 g/cm³ or less. Within the above range, the polishing rate and polishing flatness can be further enhanced while the surface defects of the object to be polished are suppressed.

For example, the difference in density between the first region (112) and the second region (114) may be 0.03 g/cm³ to 0.15 g/cm³, 0.03 g/cm³ to 0.14 g/cm³, 0.03 g/cm³ to 0.12 g/cm³, 0.03 g/cm³ to 0.10 g/cm³, 0.03 g/cm³ to 0.09 g/cm³, 0.03 g/cm³ to 0.08 g/cm³, 0.035 g/cm³ to 0.08 g/cm³, 0.035 g/cm³ to 0.07 g/cm³, 0.04 g/cm³ to 0.06 g/cm³, or 0.05 g/cm³ to 0.06 g/cm³.

The first region (112) and the second region (114) may each be disposed on the upper side of the sub pad (120). In an embodiment, the first region (112) and the second region (114) may be disposed to be positioned at the same layer on the upper side of the sub pad (120).

For example, the lower side of the first region (112) and the lower side of the second region (114) may be in contact with the upper side of the sub pad (120) together, or, if another layer or pad is interposed between the top pad (110) and the sub pad (120), they may be in contact with the upper side of the other layer or pad together.

The first region (112) and the second region (114) may be in physical contact with each other. For example, there may be no gap or void space formed between the first region (112) and the second region (114), and the side wall of the first region (112) and the side wall of the second region (114) may be in full and close contact with each other. As a result, the flow of a slurry on the polishing surface can be continued without interruption, and the contact area between the object to be polished and the top pad (110) increases, so that the polishing speed, polishing efficiency, and flatness can be further enhanced.

In an embodiment, the density of the first region (112) and the density of the second region (114) may each be 0.5 g/cm³ to 0.9 g/cm³. Within the above range, polishing characteristics such as polishing speed, removal rate, and flatness can be substantially achieved at desired levels, and surface defects such as scratches can be suppressed, thereby further improving polishing quality.

For example, the density of the first region (112) and the density of the second region (114) may each be 0.6 g/cm³ to 0.9 g/cm³, 0.65 g/cm³ to 0.90 g/cm³, 0.7 g/cm³ to 0.9 g/cm³, 0.710 g/m³ to 0.890 g/m³, 0.710 g/m³ to 0.850 g/m³, 0.720 g/m³ to 0.810 g/m³, 0.720 g/m³ to 0.80 g/m³, 0.730 g/m³ to 0.790 g/m³, or 0.740 g/m³ to 0.790 g/m³.

Within the above range, the flowability of a polishing slurry is secured, thereby suppressing the occurrence of surface defects, and the pressure applied to the object to be polished is appropriately dispersed, so that the polishing rate and surface flatness for the object to be polished can be more readily controlled within desired ranges.

The hardness of the first region (112) and that of the second region (114) may be different from each other. The difference between the hardness of the first region (112) and the hardness of the second region (114) may be 2 Shore D or more. As the top pad (110) comprises a plurality of regions having a hardness difference of 2 Shore D or more, the polishing speed and polishing rate for an object to be polished can be enhanced while the polishing flatness is improved as well.

If the difference between the hardness of the first region and the hardness of the second region is less than 2 Shore D, the difference in hardness is too small. Thus, even if the top pad comprises regions with different hardnesses, the desired level of polishing characteristics and quality may not be achieved in practice.

In an embodiment, the difference between the hardness of the first region (112) and the hardness of the second region (114) may be 20 Shore D or less. If the difference in hardness exceeds 20 Shore D, the difference in physical properties between the respective regions may become more severe, which may deteriorate the stability of the polishing pad, and the polishing of an object to be polished may be carried out unevenly, which may increase surface defects or deteriorate polishing quality such as polishing speed and polishing flatness.

For example, the difference between the hardness of the first region (112) and the hardness of the second region (114) may be 2 Shore D to 20 Shore D, 2 Shore D to 15 Shore D, 2 Shore D to 12 Shore D, 2 Shore D to 10 Shore D, 2 Shore D to 9 Shore D, 2.5 Shore D to 8 Shore D, or 3 Shore D to 6 Shore D. Within the above range, while the polishing quality is enhanced, the durability of the polishing pad and the reliability of a CMP process can be further improved.

In an embodiment, the hardness of a region having a relatively high density among the first region (112) and the second region (114) may be greater than the hardness of the other region. For example, when the first region (112) has a higher density than that of the second region (114), the hardness of the first region (112) may be greater than the hardness of the second region (114).

In an embodiment, the hardness of the first region (112) and that of the second region (114) may each be 45 Shore D to 65 Shore D. For example, the hardness of the first region (112) and that of the second region (114) may each be 45 Shore D to 63 Shore D, 48 Shore D to 63 Shore D, 50 Shore D to 62 Shore D, or 53 Shore D to 60 Shore D.

In an embodiment, the difference between the tensile elongation of the first region (112) and the tensile elongation of the second region (114) may be 15% to 150%. For example, the difference between the tensile elongation of the first region (112) and the tensile elongation of the second region (114) may be 15% to 120%, 15% to 100%, 20% to 90%, 20% to 60%, or 20% to 50%. Within the above range, it is possible to prevent the deterioration of durability and reliability due to local differences in tensile elongation in the top pad (110) and to further enhance the polishing flatness and removal rate.

In an embodiment, the tensile elongation of the first region (112) and the tensile elongation of the second region (114) may each be 50% to 200%. For example, the tensile elongation of the first region (112) and the tensile elongation of the second region (114) may each be 60% to 190%, 70% to 180%, 70% to 150%, or 80% to 130%.

In an embodiment, the tensile elongation of a region having a relatively high density among the first region (112) and the second region (114) may be smaller than the tensile elongation of the other region. For example, when the first region (112) has a higher density than that of the second region (114), the tensile elongation of the first region (112) may be smaller than the tensile elongation of the second region (114).

In another embodiment, the tensile elongation of a region having a relatively high density among the first region (112) and the second region (114) may be greater than the tensile elongation of the other region.

The first region (112) and the second region (114) may have different tensile strengths. For example, the difference between the tensile strength of the first region (112) and that of the second region (114) may be 1 N/mm² or more.

In an embodiment, the difference between the tensile strength of the first region (112) and the tensile strength of the second region (114) may be 1 N/mm² or more, 1.5 N/mm² or more, or 2 N/mm² or more, and may be 6 N/mm² or less, 5.5 N/mm² or less, or 5 N/mm² or less. For example, the difference between the tensile strength of the first region (112) and that of the second region (114) may be 1 N/mm² to 6 N/mm².

The first region (112) and the second region (114) may have various shapes, forms, or structures in the upper side direction of the top pad (110).

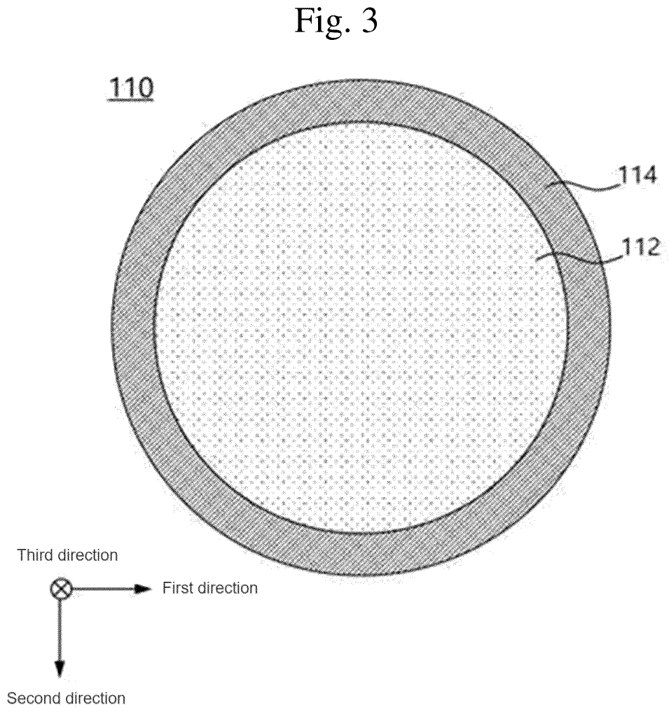

FIG. 3 is a schematic plan view showing a polishing pad according to an embodiment of the present invention.

Referring to FIG. 3, in the upper side direction of the top pad (110), the first region (112) may be located in the central region of the top pad (110), and the second region (114) may be located in the outer region of the top pad (110).

The second region (114) may be disposed to surround the first region (112) in the outer region. For example, the outer region may correspond to the remaining region of the top pad (110) excluding the central region.

In an embodiment, in the upper side direction, the first region (112) may have a circular shape, and the second region (114) may have an annular shape surrounding the circular shape. For example, the first region (112) and the second region (114) may have a concentric shape.

In another embodiment, in the upper side direction, the first region (112) may have a polygonal shape such as a triangle, a square, a trapezoid, a rhombus, or a pentagon. In such a case, the inner perimeter of the second region (114) may have a shape corresponding to the outer perimeter of the first region (112). For example, the inner perimeter of the second region (114) may be complementarily combined with the outer perimeter of the first region (112), or they may be interlocked with each other.

In an embodiment, the density of the first region (112) may be higher than the density of the second region (114). A region with a low density is disposed on the outer region of the top pad (110) to facilitate the inflow of a slurry, whereby the polishing efficiency for an object to be polished can be further increased.

In an embodiment, the density of the second region (114) may be higher than the density of the first region (112). A region with a high density is disposed on the outer region of the top pad (110), whereby polishing of an object to be polished can be performed more uniformly, and polishing flatness in the edge region can be further enhanced.

When the first region (112) has a circular shape, the radius of the first region (112) may be 5 cm to 35 cm from the center of the top pad (110). For example, the radius of the first region (112) may be 10 cm to 35 cm, 15 cm to 30 cm, or 20 cm to 30 cm from the center of the top pad (110). Within the above range, the polishing rate and polishing flatness can be further increased. In an embodiment, the radius of the top pad (110) may be 35 cm to 50 cm, for example, 36 cm to 48 cm, 36 cm to 45 cm, 36 cm to 42 cm, or 36 cm to 40 cm.

In an embodiment, when the top pad (110) is observed in the upper side direction, the area of the first region (112) may be 2% to 75% of the total area of the top pad (110). For example, the area of the first region (112) may be 4% to 70%, 5% to 70%, 5% to 60%, 5% to 50%, 8% to 40%, or 8% to 20% of the total area of the top pad (110). Within the above range, an object to be polished can be brought into even contact with both the first region (112) and the second region (114) in a polishing procedure. As a result, more uniform polishing can be performed on the entire surface of the object, and the polishing speed and polishing rate can be further enhanced. In addition, the polishing flatness can also be further increased at the edge region of the surface of the polished object.

The top pad (110) may comprise a plurality of first regions (112). In the upper side direction of the top pad (110), a plurality of first regions (112) may be physically separated from each other by the second regions (114).

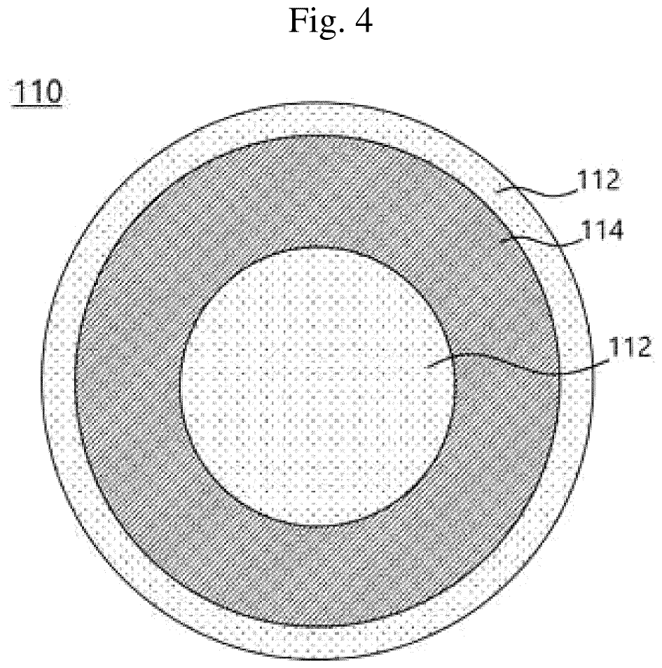

FIG. 4 is a schematic plan view showing a polishing pad according to an embodiment of the present invention.

Referring to FIG. 4, the top pad (110) may comprise two first regions (112) when observed in the upper side direction. The first regions (112) may be separated from each other by a second region (114) disposed therebetween.

For example, one of the first regions (112) may be disposed in the central region of the top pad (110), the second region (114) may be disposed in the middle region surrounding the central region, and the other of the first regions (112) may be disposed in the outer region surrounding the middle region.

When the top pad (110) is observed in the upper side direction, the first regions (112) and the second region (114) may have a concentric shape, but they are not limited thereto. For example, the outer perimeter of the first regions (112) or the second region (114) may have a polygonal shape such as a square, a rhombus, a trapezoid, or a pentagon.

The top pad (110) may comprise a plurality of first regions (112) and a plurality of second regions (114) together.

In the upper side direction of the top pad (110), a plurality of first regions (112) may be physically separated from each other by second regions (114), and the plurality of second regions (114) may be physically separated from each other by the first regions (112).

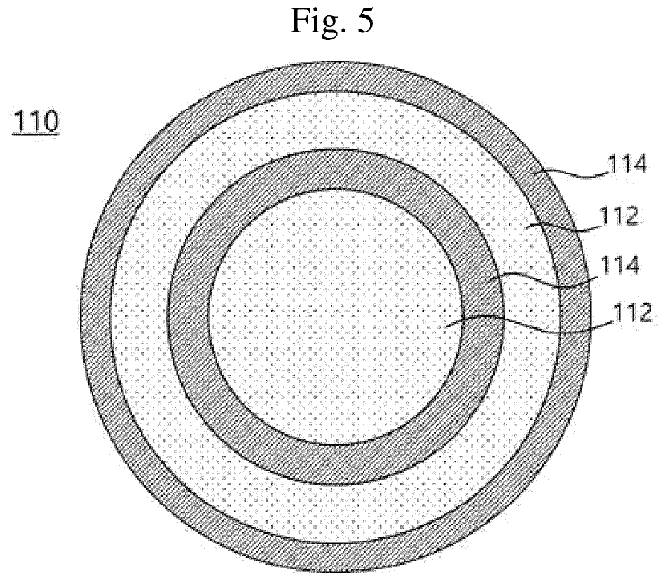

FIG. 5 is a schematic plan view showing a polishing pad according to an embodiment of the present invention.

Referring to FIG. 5, the top pad (110) may comprise two first regions (112) and two second regions (114) when observed in the upper side direction. In the upper side direction, a second region (114) may be disposed between the first regions (112), and a first region (112) may be disposed between the second regions (114).

For example, the first regions (112) and the second regions (114) may be alternately and repeatedly disposed from the center of the top pad (110) toward the outer region.

When the top pad (110) is observed in the upper side direction, the first regions (112) and the second regions (114) may have a concentric shape, and they may have a polygonal shape such as a square, a rhombus, a trapezoid, and a pentagon.

In some embodiments, the top pad (110) may further comprise a third region having a different density from those of the first region (112) and the second region (114). The density of the third region may have a value between the density of the first region (112) and the density of the second region (114).

The third region may have a hardness different from the hardnesses of the first region (112) and the second region (114). The hardness of the third region may have a value between the hardness of the first region (112) and the hardness of the second region (114).

In an embodiment, the third region may be disposed between the first region (112) and the second region (114) in the upper side direction of the top pad (110). For example, the first region (112), the third region, and the second region (114) may sequentially have a concentric shape based on the center of the top pad (110).

The top pad (110) may have a porous structure. For example, the top pad may comprise a plurality of pores on the surface and inside. The pores support the fine flow of a polishing slurry, so that the supply or discharge of the polishing slurry can be appropriately controlled by the pores.

The top pad (110) may comprise a resin. For example, the top pad (110) may comprise a urethane-based resin.

In an embodiment, the top pad (110) may comprise a cured product of a composition comprising a urethane-based prepolymer, a curing agent, and a foaming agent. Pores can be formed within the top pad (110) by the foaming agent.

As the material, the content of each component, and the shape, size, distribution, and content of pores for each region of the top pad (110) are adjusted, the density and hardness of each region can be controlled within desired ranges.

The top pad (110) may have a thickness of 0.5 mm to 5 mm. For example, the thickness of the top pad (110) may be 0.8 mm to 4.0 mm, 1.0 mm to 3.0 mm, 1.5 mm to 2.5 mm, 1.7 mm to 2.3 mm, or 2.0 mm to 2.2 mm. Within the above range, the physical properties of the polishing pad (100) required for a CMP process can be secured.

The sub pad (120) is disposed under the top pad (110) to stably support the top pad (110) while absorbing and/or dispersing the impact applied to the top pad (110). The sub pad (120) may be prepared using a nonwoven fabric, suede, or a porous pad.

The thickness of the sub pad (120) may be, for example, 0.5 mm to 4 mm, 0.6 mm to 3.5 mm, 0.8 mm to 3 mm, or 1 mm to 2 mm. Within the above range, the polishing pad (100) can be made lighter while the sub pad (120) can support the top pad (110) stably.

In some embodiments, the polishing pad (100) may further comprise an adhesive layer (130) between the top pad (110) and the sub pad (120). The adhesive layer (130) may be in contact with the lower side of the top pad (110) and the upper side of the sub pad (120) to bond the top pad (110) and the sub pad (120). Further, the adhesive layer (120) may also serve as a barrier layer to prevent a polishing slurry supplied to the top pad (110) from leaking into the sub pad (120).

In an embodiment, the adhesive layer (130) may be formed using a hot melt adhesive composition.

The hot melt adhesive composition may comprise a hot melt adhesive commonly known. In an embodiment, the hot melt adhesive may comprise a polyurethane resin, a polyester resin, an ethylene-vinyl acetate resin, a polyamide resin, and/or a polyolefin resin. They may be used alone or in combination of two or more.

The thickness of the adhesive layer (130) may be, for example, 5 μm to 100 μm, 10 μm to 80 μm, 20 μm to 70 μm, 30 μm to 60 μm, or 50 μm to 60 μm. Within the above range, the bonding strength between the top pad (110) and the sub pad (120) can be further enhanced, and the polishing pad (100) can be made lighter.

The polishing pad comprises different regions with different densities on the polishing surface, which can change the polishing rate and profile of an object to be polished, such as a wafer, in a CMP process, thereby reducing the WIWNU value and increasing the lifespan of the pad.

The average polishing rate by the polishing pad may be 1,000 Å/minute or more. Once a CMP process of semiconductor devices such as wafers has been carried out using a polishing pad, the polished thickness or polishing rate is measured at multiple points. Then, the average polishing rate is calculated as an average value of the measured polishing rates. For example, when the silicon oxide layer of a silicon wafer is polished using a ceria slurry on the polishing surface, and when the polishing rate is measured at 30 or more random locations, the average polishing rate is then calculated.

In an embodiment, the average polishing rate by the polishing pad may be 2,000 Å/minute or more. As a result, the polishing pad can provide polishing characteristics that are substantially suitable for use in a CMP process.

For example, the average polishing rate by the polishing pad may be 2,000 Å/minute or more, 2,100 Å/minute or more, 2,200 Å/minute or more, 2,300 Å/minute or more, or 2,400 Å/minute or more, for example, 2,000 Å/minute to 4,000 Å/minute, 2,200 Å/minute to 4,000 Å/minute, 2,200 Å/minute to 3,500 Å/minute, or 2,300 Å/minute to 3,400 Å/minute.

In an embodiment, the polishing rate in the edge region of the wafer by the polishing pad may be 1,500 Å/minute or more, specifically, 1,800 Å/minute or more. The edge region may be defined as a region from a point located approximately 86% of the radius of the wafer away from the center of the wafer to the periphery. For example, when the radius of a silicon wafer is 150 mm, the edge region may correspond to the region from a point 130 mm away from the center of the wafer to the periphery.

For example, when the silicon oxide layer of a silicon wafer is polished using a ceria slurry on the polishing surface, and when the polishing rate is measured at 30 or more random locations in the edge region, the polishing rate of the edge region is then calculated as an average value thereof.

The polishing rate of the edge region by the polishing pad may be 1,900 Å/minute or more, 2,000 Å/minute or more, 2,100 Å/minute or more, or 2,200 Å/minute or more, for example, 1,800 Å/minute to 4,000 Å/minute, 1,900 Å/minute to 3,500 Å/minute, 2,000 Å/minute to 3,500 Å/minute, or 2,100 Å/minute to 3,400 Å/minute.

Within-wafer non-uniformity (WIWNU) is a value related to polishing flatness in a CMP process using a polishing pad. Once a CMP process of semiconductor devices such as wafers has been carried out using a polishing pad, the polished thickness or polishing rate is measured at multiple points. Then, it is calculated using the following equation.

Within-wafer non-uniformity (%)=(standard deviation of polishing rate (Å/minute)/average polishing rate (Å/minute))×100

The standard deviation of the polishing rate may be calculated using the following equation.

$$Standard deviation of polishing rate = \sqrt{\frac{\sum {( RR - {RR}_{avg} )}^{2}}{n}}$$

In the above equation, RR is the polishing rate measured at each point, RR_{avg} is the average polishing rate (average of the polishing rate measurements), and n is the number of the polishing rate measurements.

According to an embodiment, when the silicon oxide layer of a silicon wafer is polished using a ceria slurry on the polishing surface, and when the polishing rate is measured at 30 or more random locations in the edge region, the WIWNU of the edge region calculated by the above equation may be 8% or less, specifically, 5.5% or less.

For example, the WIWNU of the polishing pad may be 5% or less, 4.9% or less, 4.8% or less, 4.7% or less, 4.6% or less, 4.5% or less, or 4.4% or less. The lower limit of the WIWNU is not particularly limited, but it may be, for example, 0% or more, 1% or more, 2% or more, 3% or more, or 4% or more. Specifically, the WIWNU of the polishing pad may be 0% to 5%, 0% to 4.8%, 1% to 4.7%, or 1% to 4.6%.

### Process for Preparing a Polishing Pad

In the process for preparing a polishing pad according to embodiments of the present invention, a first top pad layer may be attached to a portion of the upper side of a sub pad. A second top pad layer may be attached to another portion of the upper side of the sub pad.

The first top pad layer and the second top pad layer may have different densities. The difference between the density of the first top pad layer and the density of the second top pad layer may be 0.03 g/cm³ or more.

The first top pad layer and the second top pad layer may be attached to the sub pad to form the top pad described above. The first top pad layer may correspond to the first region of the top pad, and the second top pad layer may correspond to the second region of the top pad.

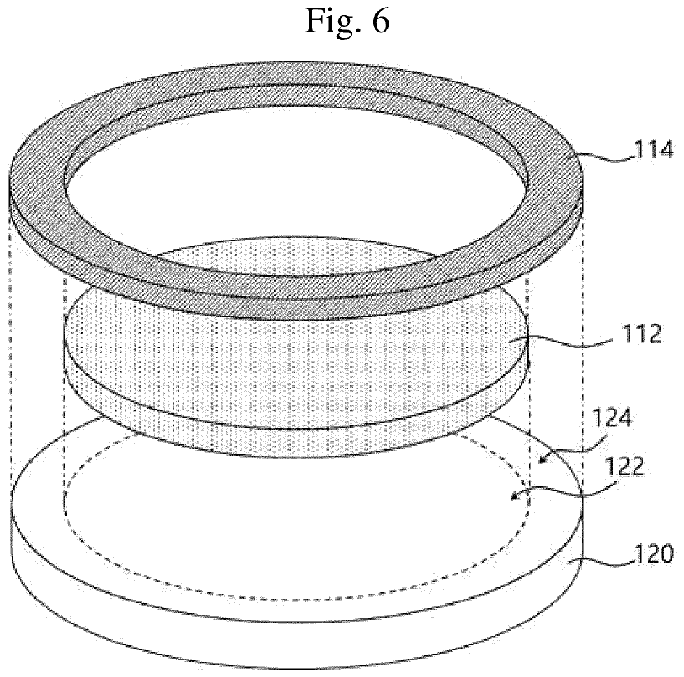

FIG. 6 is a perspective view showing a polishing pad according to an embodiment of the present invention.

Referring to FIG. 6, the upper side of the sub pad (120) may comprise a third region (122) and a fourth region (124). The third region (122) and the fourth region (124) may be regions designed and partitioned in advance on the upper side of the sub pad (120) in accordance with the shapes of the first region and the second region of the top pad. The first top pad layer (112) may have a shape corresponding to the third region (122), and the second top pad layer (114) may have a shape corresponding to the fourth region (124).

The first top pad layer (112) may be attached to the third region (122) of the sub pad (120). The first top pad layer (112) may be directly bonded to the third region (122) or may be attached to the third region (122) via a hot melt adhesive.

The second top pad layer (114) may be attached to the fourth region (124) of the sub pad (120). The second top pad layer (114) may be directly bonded to the fourth region (124) or may be attached to the fourth region (124) via a hot melt adhesive.

The first top pad layer (112) and the second top pad layer (114) may be in close contact with each other. For example, the first top pad layer (112) and the second top pad layer (114) may have a form in which they are interlocked with each other or a form in which they are complementarily combined with each other.

The first top pad layer (112) and the second top pad layer (114) may each be prepared using a raw material mixture comprising a urethane-based prepolymer, a curing agent, and a foaming agent.

A “prepolymer” generally refers to a polymer having a relatively low molecular weight wherein the degree of polymerization is adjusted to an intermediate level for the sake of conveniently molding a product in the process of producing the same. A prepolymer may be molded by itself or after a reaction with another polymerizable compound. For example, a prepolymer may be prepared by reacting an isocyanate compound with a polyol.

The urethane-based prepolymer may be prepared by reacting an isocyanate compound with a polyol.

For example, the isocyanate compound may comprise at least one compound selected from the group consisting of toluene diisocyanate (TDI), naphthalene-1,5-diisocyanate, p-phenylene diisocyanate, tolidine diisocyanate, 4,4′-diphenyl methane diisocyanate, hexamethylene diisocyanate, dicyclohexylmethane diisocyanate, and isophorone diisocyanate.

For example, the polyol may comprise at least one compound selected from the group consisting of a polyether polyol, a polyester polyol, a polycarbonate polyol, and an acryl polyol.

In an embodiment, the polyol may have a weight average molecular weight (Mw) of 300 g/mole to 3,000 g/mole.

In an embodiment, the urethane-based prepolymer may be a polymer prepared by reacting an isocyanate compound comprising toluene diisocyanate and a polyol comprising polytetramethylene ether glycol.

In some embodiments, the urethane-based prepolymer may have a weight average molecular weight of 500 g/mole to 3,000 g/mole. Specifically, the urethane-based prepolymer may have a weight average molecular weight of 600 g/mole to 2,000 g/mole or 800 g/mole to 1,000 g/mole.

In an embodiment, the urethane-based prepolymer may have an isocyanate terminal group (terminal NCO) content (NCO %) of 5% by weight to 15% by weight based on the total weight of the urethane-based prepolymer. For example, the terminal NCO content (NCO %) of the urethane-based prepolymer may be 6% by weight to 13% by weight, 7% by weight to 12% by weight, 7.5% by weight to 11% by weight, or 8% by weight to 10% by weight.

The foaming agent may comprise a solid phase foaming agent, a liquid phase foaming agent, or a gas phase foaming agent. Specifically, the foaming agent may comprise a solid phase foaming agent. Pores can be formed on the surface and inside of the top pad by the foaming agent.

When a solid phase foaming agent is used, the shape, size, content, and distribution of pores can be controlled more precisely than when a liquid phase or gas phase foaming agent is used. In addition, since the solid phase foaming agent has an outer shell and a void, the shape of the micropores contained within the top pad can be maintained even during a CMP process, which can further improve the polishing performance.

In some embodiments, the solid phase foaming agent may be purified by a purification system. As a result, the solid phase foaming agent can have uniform density, average particle size, solvent resistance, thermal resistance, and the like.

In an embodiment, the solid phase foaming agent may have an average particle diameter (D₅₀) of 1 μm to 20 μm. The average particle diameter (D₅₀) may be defined as the particle diameter at a volume fraction of 50% in a volume particle distribution obtained by accumulating the particles in order of increasing particle diameter. For example, the purification system can filter out particles having excessively small or large particle sizes, so that the average particle size of the solid phase foaming agent can be controlled within the above range.

In some embodiments, the solid phase foaming agent may comprise thermally expanded particles. When the solid phase foaming agent comprises thermally expanded particles, the D50 of the solid phase foaming agent may refer to the average particle diameter in a thermally expanded state. The thermally expanded particles may be obtained by thermally expanding thermally expandable particles.

The thermally expandable particles may comprise a shell comprising a thermoplastic resin and a foaming agent encapsulated inside the shell. The thermoplastic resin may comprise at least one copolymer selected from the group consisting of a vinylidene chloride-based copolymer, an acrylonitrile-based copolymer, a methacrylonitrile-based copolymer, and an acryl-based copolymer.

In an embodiment, the foaming agent encapsulated in the inside may comprise a hydrocarbon compound having 1 to 7 carbon atoms. For example, the foaming agent encapsulated in the inside may comprise a low molecular weight hydrocarbon such as ethane, ethylene, propane, propene, n-butane, isobutane, butene, isobutene, n-pentane, isopentane, neopentane, n-hexane, heptane, petroleum ether, and the like; a chlorofluorohydrocarbon such as trichlorofluoromethane (CCl₃F), dichlorodifluoromethane (CCl₂F₂), chlorotrifluoromethane (CClF₃), tetrafluoroethylene (CClF₂—CClF₂), and the like; or tetramethylsilane, trimethylethylsilane, trimethylisopropylsilane, trimethyl-n-propylsilane, and the like. They may be used alone or in combination of two or more.

The curing agent may comprise an amine compound and/or an alcohol compound. For example, the curing agent may comprise at least one compound selected from the group consisting of an aromatic amine, an aliphatic amine, an aromatic alcohol, and an aliphatic alcohol.

For example, the curing agent may comprise at least one selected from the group consisting of 4,4′-methylenebis(2-chloroaniline) (MOCA), diethyltoluenediamine, diaminodiphenylmethane, diaminodiphenyl sulphone, m-xylylene diamine, isophoronediamine, ethylenediamine, diethylenetriamine, triethylenetetramine, polypropylenediamine, polypropylenetriamine, ethylene glycol, diethylene glycol, dipropylene glycol, butanediol, hexanediol, glycerin, trimethylolpropane, and bis(4-amino-3-chlorophenyl)methane.

The content of the curing agent may be 3.0 parts by weight to 40 parts by weight based on 100 parts by weight of the raw material mixture. The content of the foaming agent may be 0.5 part by weight to 5.0 parts by weight based on 100 parts by weight of the raw material mixture.

The urethane-based prepolymer and the curing agent may be mixed at a molar equivalent ratio of 1:0.8 to 1:1.2, or a molar equivalent ratio of 1:0.9 to 1:1.1, based on the number of moles of the reactive groups in each molecule. Here, “the number of moles of the reactive groups in each molecule” refers to, for example, the number of moles of the isocyanate group in the urethane-based prepolymer and the number of moles of the reactive groups (e.g., amine group, alcohol group, and the like) in the curing agent. The urethane-based prepolymer and the curing agent may be added during the mixing process so as to satisfy the molar equivalent ratio described above and react with each other. As the curing reaction is carried out at the above reaction ratio, the curing reaction can be optimized, whereby it is possible to provide a polishing pad with the physical properties required for a CMP process.

In some embodiments, the raw material mixture may comprise 55 parts by weight to 96.5 parts by weight of the urethane-based prepolymer, 0.5 part by weight to 5.0 parts by weight of the foaming agent, and 3.0 parts by weight to 40 parts by weight of the curing agent based on 100 parts by weight of the raw material mixture. For example, the raw material mixture may comprise 66.5 parts by weight to 96.5 parts by weight of the urethane-based prepolymer, 0.5 part by weight to 3.5 parts by weight of the foaming agent, and 5.0 parts by weight to 35 parts by weight of the curing agent based on 100 parts by weight of the raw material mixture.

In some embodiments, the raw material mixture may further comprise a surfactant. The surfactant may prevent the pores to be formed from overlapping and coalescing with each other. For example, the surfactant may be a silicone-based nonionic surfactant. But other surfactants may be variously selected depending on the physical properties required for the polishing pad.

As the silicone-based nonionic surfactant, a silicone-based nonionic surfactant having a hydroxyl group may be used alone, or a silicone-based nonionic surfactant having a hydroxyl group and a silicone-based nonionic surfactant having no hydroxyl group may be used together.

The content of the surfactant may be 0.1 part by weight to 2 parts by weight, 0.2 part by weight to 1.8 parts by weight, 0.2 part by weight to 1.7 parts by weight, 0.2 part by weight to 1.6 parts by weight, or 0.2 part by weight to 1.5 parts by weight, based on 100 parts by weight of the raw material mixture. Within the above range, pores derived from the foaming agent can be stably formed and maintained during the curing or molding process.

The raw material mixture may be reacted to form a solid polyurethane. For example, the isocyanate terminal group (NCO group) in the urethane-based prepolymer can react with the amine group, the alcohol group, and the like in the curing agent during the reaction. The solid phase foaming agent can be uniformly dispersed in the solid polyurethane to form a plurality of pores without participating in the curing reaction.

The density of the first top pad layer (112) and that of the second top pad layer (114) may be controlled by adjusting the content of each component in the raw material mixture. For example, the first top pad layer (112) and the second top pad layer (114) may comprise substantially the same resin.

In an embodiment, the density of the first top pad layer (112) and that of the second top pad layer (114) may each be controlled within desired ranges by adjusting the content of the foaming agent in the raw material mixture. As the content of the foaming agent in the raw material mixture increases, the pore volume of the top pad may increase, thereby decreasing the density. As the content of the foaming agent decreases, the top pad may have a denser structure, which can increase the density.

In an embodiment, the solid polyurethane may be prepared in a sheet form.

In some embodiments, the forming or curing process may be carried out using a mold. For example, the raw material mixture may be injected into a mold and molded. Specifically, the raw material mixture stirred in a mixing head or the like may be injected into a mold to fill the inside thereof.

In an embodiment, in the process of mixing and dispersing the urethane-based prepolymer, the solid phase foaming agent, and the curing agent, they are mixed at a rotational speed of the mixing head of 500 rpm to 10,000 rpm, specifically, 1,000 rpm to 9,000 rpm, 2,000 rpm to 9,000 rpm, 3,000 to 8,000 rpm, 4,000 to 8,000 rpm, or 5,000 rpm to 7,000 rpm. Within the above range, the shape of the pores contained in the polishing pad can be more readily controlled within desired ranges.

The reaction between the urethane-based prepolymer and the curing agent is completed in the mold to thereby produce a molded body in the form that conforms to the shape of the mold.

The molded body may be appropriately sliced or cut into a sheet for the production of a top pad. For example, the raw material mixture may be molded in a mold having a height of 5 times to 50 times the thickness of a top pad to be finally produced, and the molded body is then sliced in the same thickness to produce a plurality of sheets for the top pads at the same time. The sheets for top pads may be processed into a desired shape to prepare the first top pad layer and the second top pad layer, respectively.

In an embodiment, a reaction retarder as a reaction rate controlling agent may be further mixed in order to secure a sufficient solidification time.

The reaction retarder may comprise at least one selected from the group consisting of triethylenediamine, dimethylethanolamine, tetramethylbutanediamine, 2-methyl-triethylenediamine, dimethylcyclohexylamine, triethylamine, triisopropanolamine, 1,4-diazabicyclo(2,2,2)octane, bis(2-methylaminoethyl) ether, trimethylaminoethylethanolamine, N,N,N,N,N″-pentamethyldiethyldimethylaminoethylamine, dimethylaminopropylamine, benzyldimethylamine, N-ethylmorpholine, N,N-dimethylaminoethylmorpholine, N,N-dimethylcyclohexylamine, 2-methyl-2-azanobornene, dibutyltin dilaurate, stannous octoate, dibutyltin diacetate, dioctyltin diacetate, dibutyltin maleate, dibutyltin di-2-ethylhexanoate, and dibutyltin dimercaptide.

### Process for Preparing a Semiconductor Device

In the process for preparing a semiconductor device according to embodiments of the present invention, a semiconductor substrate may be polished using the polishing pad described above.

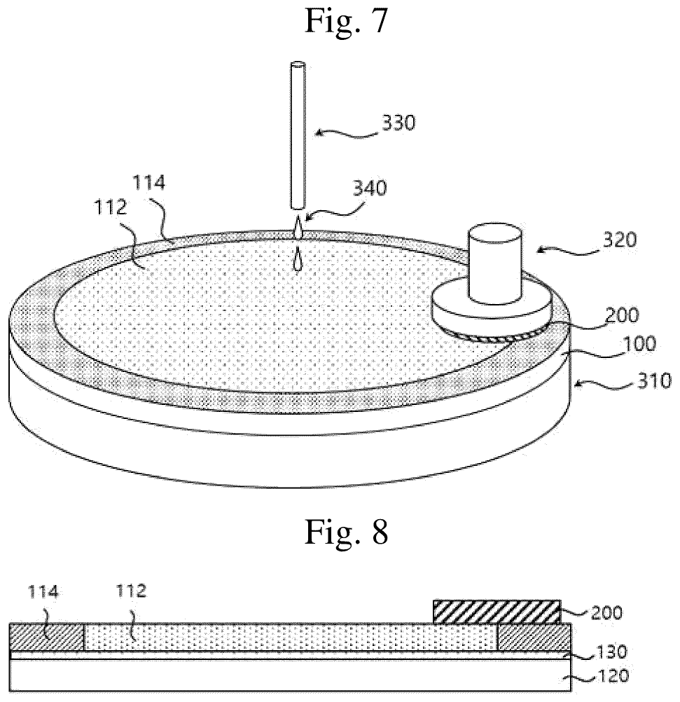

FIG. 7 is a schematic process flow diagram for illustrating a process for preparing a semiconductor device according to an embodiment of the present invention.

Referring to FIG. 7, a polishing pad (100) may be mounted on a platen (310). The polishing pad (100) may be mounted on the platen (310) with the upper side of the top pad facing upward. For example, a first region (112) and a second region (114) may be exposed on the polishing surface of the polishing pad (100) mounted on the platen (310).

A semiconductor substrate (200) may be positioned on the polishing pad (100) such that the polishing surface of the polishing pad (100) and the surface (surface to be polished) of the semiconductor substrate (200) are in contact. For example, the semiconductor substrate (200) is mounted on a polishing head (320) and can be in direct contact with the polishing surface of the polishing pad (100).

In an embodiment, a polishing slurry (340) may be sprayed onto the polishing pad (100) for polishing. The polishing slurry (340) may be sprayed through a nozzle (330). The flow rate of the polishing slurry (340) sprayed through the nozzle (330) may be controlled within the range of 10 ml/minute to 1,000 ml/minute or 50 ml/minute to 500 ml/minute.

The polishing pad (100) and the semiconductor substrate (200) may be rotated relative to each other to polish the surface, to be polished, of the semiconductor substrate (200). In an embodiment, the rotation direction of the polishing pad (100) and the rotation direction of the semiconductor substrate (200) may be the same. In an embodiment, the rotation direction of the polishing pad (100) and the rotation direction of the semiconductor substrate (200) may be opposite to each other.

FIG. 8 is a schematic cross-sectional view for illustrating the contact surface of a polishing pad and a semiconductor substrate.

Referring to FIG. 8, the surface of a semiconductor substrate (200) to be polished may be in contact with both a first region (112) and a second region (114) of a polishing pad (100). As a result, in the procedure of relative rotation of the polishing pad (100) and the semiconductor substrate (200), polishing by the first region (112) and polishing by the second region (114) may be carried out simultaneously on the surface, to be polished, of the semiconductor substrate (200).

Accordingly, thanks to the difference in density in the respective regions of the polishing surface, the polishing speed and polishing efficiency for the semiconductor substrate (200) can be increased, while the overall flatness of the semiconductor substrate (200) upon the polishing process can be enhanced. In addition, as the supply and spread of a slurry are facilitated by the region with a low density, and as the entire area is uniformly polished by the region with a high density, enhanced polishing rates and uniformity can be provided even in the edge region of the surface to be polished.

In an embodiment, the rotation speed of the polishing pad (100) and the rotation speed of the semiconductor substrate (200) may be 10 rpm to 500 rpm, 30 rpm to 200 rpm, or 50 rpm to 150 rpm, respectively.

In an embodiment, the semiconductor substrate (200) mounted on a polishing head (320) is pressed against the polishing surface of the polishing pad (100) at a predetermined load. The load applied to the polishing surface of the polishing pad (100) and the surface, to be polished, of the semiconductor substrate (200) by the polishing head (320) may be 1 gf/cm² to 1,000 gf/cm² or 10 gf/cm² to 800 gf/cm².

In an embodiment, in order to maintain the polishing surface of the polishing pad (100) in a state suitable for polishing, the process for preparing a semiconductor device may further comprise processing the polishing surface of the polishing pad (100) with a conditioner. The conditioning process for the polishing surface may be carried out simultaneously with the polishing of the semiconductor substrate (200).

Hereinafter, the present invention is explained in detail by the following Examples. However, these examples are set forth to illustrate the present invention, and the scope of the present invention is not limited thereto.

### EMBODIMENTS FOR CARRYING OUT THE INVENTION

### Example 1

### Preparation of a Urethane-Based Prepolymer

Toluene diisocyanate (TDI, BASF) as an isocyanate compound and polytetramethylene ether glycol (PTMEG, Korea PTG) as a polyol were mixed such that the content of the NCO group was 9.1% by weight and then reacted. In order to minimize side reactions during the synthesis, the inside of the reactor was filled with nitrogen (N₂) as an inert gas at a reaction temperature of 75° C. with stirring for 3 hours to carry out the reaction, thereby preparing a urethane-based prepolymer having a content of the NCO group of 9.1% by weight.

### Preparation of a First Top Pad

The urethane-based prepolymer prepared above, triethylenediamine (Dow) as a curing agent, and microcapsules (Expancel 044DU20, Noutyon) as a solid phase foaming agent were used.

In a casting machine equipped with feeding lines for a urethane-based prepolymer, a curing agent, an inert gas, and a solid phase foaming agent, the urethane-based prepolymer prepared in the preparation example above was charged, and the curing agent of triethylenediamine was charged to the curing agent tank. The solid phase foaming agent was quantified in an amount of 2.0 parts by weight based on 100 parts by weight of the urethane-based prepolymer, curing agent, and solid foaming agent and charged to the prepolymer tank.

The urethane-based prepolymer, the curing agent, and the solid phase foaming agent were fed to the mixing head and stirred at a rotation speed of 6,000 rpm. The molar equivalent ratio of the NCO group in the urethane-based prepolymer to the reactive groups in the curing agent was adjusted to 1:1, and the total feed rate was maintained at a rate of 10 kg/minute.

The mixed raw materials were injected into a mold (1,000 mm×1,000 mm×3 mm) and reacted to obtain a molded body in the form of a solid cake. The top and bottom of the molded body were each ground by a thickness of 0.5 mm and subjected to surface milling and groove forming processes to obtain a first top pad having a thickness of 2 mm. The density of the first top pad was measured to be 0.79 g/cm³.

### Preparation of a Second Top Pad

A second top pad was prepared using the same method as the first top pad, except that the solid foaming agent was mixed in an amount of 3.0 parts by weight based on 100 parts by weight of the urethane-based prepolymer, curing agent, and solid phase foaming agent. The density of the second top pad was measured to be 0.75 g/cm³.

### Preparation of a Polishing Pad

A sub pad (a thickness of 1.2 mm) with a radius of 76 cm was prepared in which a polyester fiber nonwoven fabric was impregnated with a polyurethane resin. The upper side of the sub pad was divided into an inner region of a concentric circle with a radius of 25 cm and an outer region surrounding the inner region.

The first top pad was processed into a shape corresponding to the inner region of the sub pad and attached to the inner region using a hot melt adhesive. The second top pad was processed into a shape corresponding to the outer region of the sub pad and attached to the outer region using a hot melt adhesive.

### Example 2

A polishing pad was prepared in the same manner as in Example 1, except that the second top pad was attached to the inner region of the sub pad, and the first top pad was attached to the outer region of the sub pad.

### Example 3

### Preparation of a Third Top Pad

A third top pad was prepared using the same method as the first top pad, except that the solid foaming agent was mixed in an amount of 4.5 parts by weight based on 100 parts by weight of the urethane-based prepolymer, curing agent, and solid phase foaming agent. The density of the third top pad was measured to be 0.70 g/cm³.

### Preparation of a Polishing Pad

A polishing pad was prepared in the same manner as in Example 1, except that the third top pad, instead of the second top pad, was attached to outer region of the sub pad.

### Example 4

A polishing pad was prepared in the same manner as in Example 3, except that the third top pad was attached to the inner region of the sub pad, and the first top pad was attached to the outer region of the sub pad.

### Comparative Example 1

A first top pad was prepared in the same method as in Example 1, and the first top pad was attached to the entire upper side of the sub pad to prepare a polishing pad.

### Comparative Example 2

A second top pad was prepared in the same method as in Example 1, and the second top pad was attached to the entire upper side of the sub pad to prepare a polishing pad.

### Comparative Example 3

A third top pad was prepared in the same method as in Example 3, and the third top pad was attached to the entire upper side of the sub pad to prepare a polishing pad.

### Measurement of the Physical Properties of the Top Pad

Density: The top pad was cut into a size of 2 cm×2 cm (thickness: 2 mm) and then allowed to stand for 16 hours under the conditions of a temperature of 23±2° C. and a humidity of 50±5%. The density of the top pad was measured using 3D CMM equipment CRYSTA-Apex S9106 (Mitutoyo).

Hardness: The top pad was cut into a size of 2 cm×2 cm (thickness: 2 mm) and then allowed to stand for 16 hours under the conditions of a temperature of 23±2° C. and a humidity of 50±5%. The Shore D hardness of the top pad was measured using a digital durometer HPE 3 Shore D (Bareiss).

Tensile elongation: Specimens having a size of 150 mm×10 mm were collected from five locations within the pad, and the tensile elongation of the top pad was measured using AG-X Plus (SHIMADZU).

The physical properties of the prepared top pad are shown in Table 1 below.

TABLE 1

| | | | Tensile |
|---|---|---|---|
| | Density | Hardness | elongation |
| | (g/cm³) | (Shore D) | (%) |
| First top pad | 0.79 | 59.0 | 120 |
| Second top pad | 0.75 | 56.0 | 90 |
| Third top pad | 0.70 | 50.0 | 180 |

The density in the respective regions and the difference in density of the top pad in the polishing pads prepared in the Examples and Comparative Examples were calculated and shown in Table 2 below.

In Table 2 below, the difference in density is expressed as an absolute value.

TABLE 2

| | Inner region | | Outer region | | Density |
|---|---|---|---|---|---|
| | | Density | | Density | difference |
| | Top pad type | (g/cm³) | Top pad type | (g/cm³) | (g/cm³) |
| Ex. 1 | First top pad | 0.79 | Second top pad | 0.75 | 0.04 |
| Ex. 2 | Second top pad | 0.75 | First top pad | 0.79 | 0.04 |
| Ex. 3 | First top pad | 0.79 | Third top pad | 0.70 | 0.09 |
| Ex. 4 | Third top pad | 0.70 | First top pad | 0.79 | 0.09 |
| C. Ex. 1 | First top pad | 0.79 | First top pad | 0.79 | 0 |
| C. Ex. 2 | Second top pad | 0.75 | Second top pad | 0.75 | 0 |
| C. Ex. 3 | Third top pad | 0.70 | Third top pad | 0.70 | 0 |

### Test Example 1: Evaluation of Polishing Rate

A silicon wafer having a diameter of 300 mm with silicon oxide (SiO₂) deposited by a CVD process was prepared. Each polishing pad was fixed onto the platen of CMP equipment, and the silicon wafer was set with the silicon oxide layer thereof facing downward. Then, a CMP process was carried out. In the Examples, the silicon wafer was set such that the silicon oxide layer was in contact with both the inner and outer regions of the polishing pad.

The silicon oxide layer was polished under a polishing load of 4.0 psi while the platen was rotated at a speed of 150 rpm for 60 seconds and a calcined silica slurry was supplied onto the polishing pad at a rate of 250 ml/minute. Upon completion of the polishing, the silicon wafer was detached from the carrier, mounted in a spin dryer, washed with deionized water (DIW), and then dried with nitrogen for 15 seconds. The changes in the film thickness (polished thickness) of the silicon wafer before and after the polishing were measured using a spectral reflectometer type thickness measuring instrument (SI-F80R, Keyence).

The region from the center of the silicon wafer to a radius of 60 mm was defined as the center region (Center), the region from a radius of 60 mm to a radius of 130 mm was defined as the middle region (Middle), and the region from a radius of 130 mm to a radius of 150 mm was defined as the edge region (Edge). The polishing rate was calculated according to the following equation.

Polishing rate (Å/minute)=average polished thickness of a silicon wafer (A)/polishing time (minute)

The average polishing rate was calculated as the average value of all values (polished thickness) measured in the center, middle, and edge regions of the silicon wafer.

In addition, the polishing rate in the edge region was calculated as the average value of the measured values (polished thickness) in the edge region.

The evaluation results are shown in Table 3 below.

### Test Example 2: Evaluation of within-Wafer Non-Uniformity

The within-wafer non-uniformity (WIWNU) in the edge region was calculated according to the following equation from the measured values for the edge region in Test Example 1.

$$Within - wafer non - uniformity ( \% ) = ( standard deviation of polishing rate ( Å / minute ) / average polishing rate ( Å / minute ) ) \times 100$$

The evaluation results are shown in Table 3 below.

TABLE 3

Polishing characteristics

| | Avg. | Polishing | Within-wafer |
|---|---|---|---|
| | polishing | rate in the | non-uniformity |
| | rate | edge region | in the edge region |
| | (Å/min.) | (Å/min.) | (at edge) |
| Ex. 1 | 2311 | 2122 | 4.6 |
| Ex. 2 | 2221 | 2082 | 4.4 |
| Ex. 3 | 2128 | 1955 | 7.6 |
| Ex. 4 | 1124 | 1510 | 5.1 |
| C. Ex. 1 | 2284 | 2184 | 6.3 |
| C. Ex. 2 | 2167 | 2085 | 5.9 |
| C. Ex. 3 | 989 | 940 | 10.7 |

Referring to Table 3, in Examples 1 and 2, the first top pad and the second top pad were respectively located in the inner region or the outer region, whereby a polishing rate substantially equivalent to, or higher than, that of Comparative Example 1, in which only the first top pad was used, and Comparative Example 2, in which only the second top pad was used, was provided; and the polishing flatness in the edge region was improved.

In Example 1, the top pad layer with a low density was disposed in the outer region to provide a relatively high average polishing rate and a relatively high polishing rate in the edge region. In Example 2, the top pad layer with a low density was disposed in the inner region to provide relatively uniform polishing in the edge region.

In addition, in Examples 3 and 4, in which the first top pad and the third top pad were respectively positioned together in the inner region or the outer region, higher average polishing rates and higher polishing rates in the edge region were provided as compared with Comparative Example 3, in which only the third top pad was used; and the polishing flatness in the edge region was significantly improved.

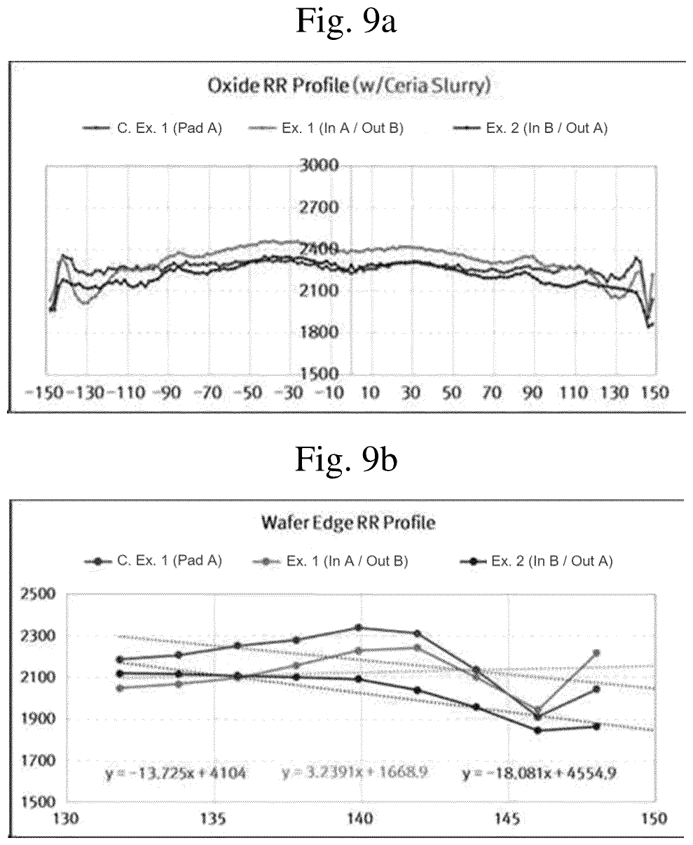

FIG. 9a is a graph showing a polishing rate profile with respect to the distance from the center of a silicon wafer measured in Test Example 1 for each of Example 1, Example 2, and Comparative Example 1.

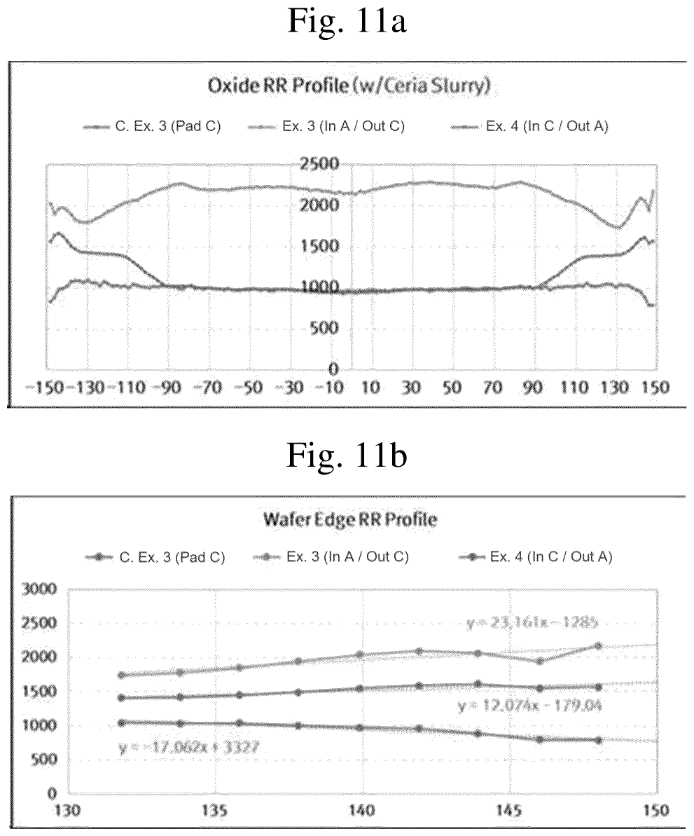

FIG. 9b is an enlarged graph of the polishing rate profile in the edge region in FIG. 11a. In FIGS. 9a and 9b, Pad A is the first top pad, and “In A/Out B” means that the first top pad (A) was located in the inner region and the second top pad (B) was located in the outer region.

Referring to FIGS. 9a and 9b, in Examples 1 and 2, a higher polishing rate was provided in the center region than in Comparative Example 1, and polishing was performed relatively uniformly in the edge region. In Comparative Example 1, the deviation in the polishing rate in the edge region was increased as compared with the Examples.

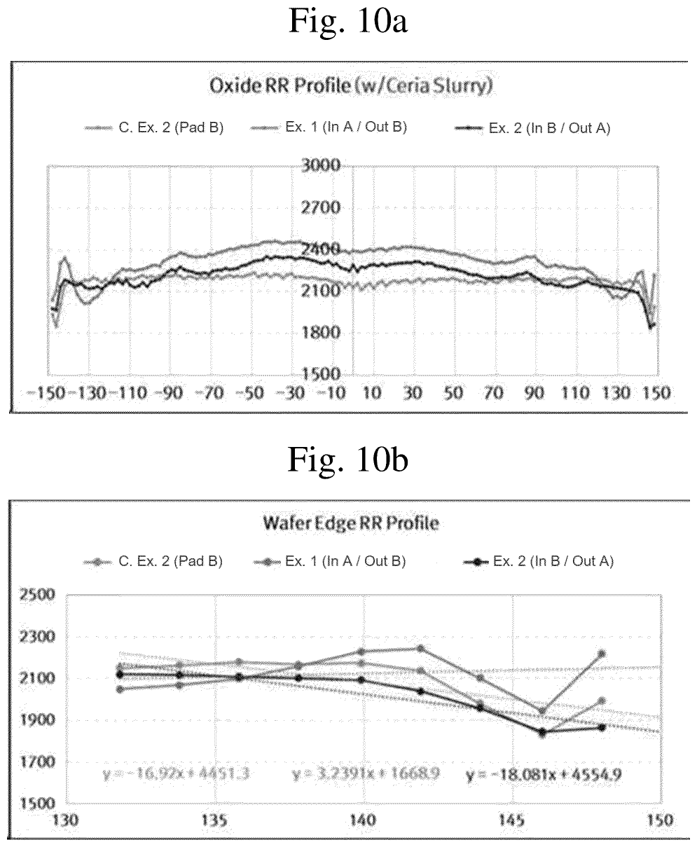

FIG. 10a is a graph showing a polishing rate profile with respect to the distance from the center of a silicon wafer measured in Test Example 1 for each of Example 1, Example 2, and Comparative Example 2.

FIG. 10b is an enlarged graph of the polishing rate profile in the edge region in FIG. 10a. In FIGS. 10a and 10b, Pad B refers to the second top pad.

Referring to FIGS. 10a and 10b, in Examples 1 and 2, overall high polishing rates were provided not only in the center region but also in the middle region as compared with Comparative Example 2. In addition, in the Examples, the deviation of the polishing rate by distance in the edge region was reduced as compared with Comparative Example 2.

FIG. 11a is a graph showing a polishing rate profile with respect to the distance from the center of a silicon wafer measured in Test Example 1 for each of Example 3, Example 4, and Comparative Example 3.

FIG. 11b is an enlarged graph of the polishing rate profile in the edge region in FIG. 11a. In FIGS. 11a and 11b, Pad C refers to the third top pad.

Referring to FIGS. 11a and 11b, in Examples 3 and 4, overall high polishing rates were provided as compared with Comparative Example 3; and the polishing rates in the edge region were significantly enhanced as compared with Comparative Example 3. In addition, in Examples 3 and 4, the polishing rates by region in the edge region were relatively uniform.

### REFERENCE NUMERAL OF THE DRAWINGS

100: polishing pad, 110: top pad, 112: first region, 114: second region, 120: sub pad, 130: adhesive layer, 200: semiconductor substrate, 310: platen, 320: polishing head, 330: nozzle, 340: polishing slurry

1. A polishing pad, which comprises a sub pad and a top pad disposed on the sub pad and comprising a first region and a second region having different densities,
wherein the difference between the density of the first region and the density of the second region is 0.03 g/cm³ or more.

2. The polishing pad of claim 1, wherein the difference between the density of the first region and the density of the second region is 0.03 g/cm³ to 0.15 g/cm³.

3. The polishing pad of claim 1, wherein the first region and the second region are positioned at the same layer on the upper side of the sub pad in physical contact with each other.

4. The polishing pad of claim 1, wherein in the upper side direction of the top pad, the first region is located in the central region of the top pad, and the second region is located in the outer region of the top pad to surround the first region.

5. The polishing pad of claim 4, wherein the density of the first region is higher than the density of the second region.

6. The polishing pad of claim 4, wherein the density of the second region is higher than the density of the first region.

7. The polishing pad of claim 4, wherein in the upper side direction of the top pad, the first region has a circular shape, and the second region has an annular shape surrounding the first region.

8. The polishing pad of claim 4, wherein the area of the first region is 2% to 75% of the total area of the top pad.

9. The polishing pad of claim 1, wherein the density of the first region and the density of the second region are each 0.5 g/cm³ to 0.9 g/cm³.

10. The polishing pad of claim 1, wherein the first region and the second region have different hardnesses.

11. The polishing pad of claim 10, wherein the difference between the hardness of the first region and the hardness of the second region is 2 Shore D to 20 Shore D.

12. The polishing pad of claim 1, wherein the first region and the second region have different tensile elongations, and the difference between the tensile elongation of the first region and the tensile elongation of the second region is 15% to 150%.

13. A process for preparing a polishing pad, which comprises:
attaching a first top pad layer to a portion of the upper side of a sub pad, and
attaching a second top pad layer having a different density from that of the first top pad layer to another portion of the upper side of the sub pad,
wherein the difference between the density of the first top pad layer and the density of the second top pad layer is 0.03 g/cm³ or more.

14. A process for preparing a semiconductor device, which comprises:
mounting the polishing pad of claim 1 on a platen;
mounting a semiconductor substrate on a head such that the surface, to be polished, of the semiconductor substrate is brought into contact with the top pad of the polishing pad; and
rotating the polishing pad and the semiconductor substrate relative to each other to polish the surface, to be polished, of the semiconductor substrate.

15. The process for preparing a semiconductor device according to claim 14, wherein the surface, to be polished, of the semiconductor substrate is in contact with both the first region and the second region of the polishing pad.
